(19) United States
(12) Patent Application Publication
(10) Pub. No.: US 2008/0265410 A1
(43) Pub. Date: Oct. 30, 2008

(54) Wafer level package

(75) Inventors: Shu-Ming Chang, Hsinchu (TW); Yu-Jiau Hwang, Hsinchu (TW); Yuan-Chang Lee, Hsinchu (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/979,046

(22) Filed: Oct. 30, 2007

(30) Foreign Application Priority Data
Apr. 25, 2007 (TW) 096114667

(51) Int. Cl. H01L 23/48

(52) U.S. Cl. 257/737; 257/E23.01

(57) ABSTRACT

A wafer level package includes a substrate, a passivation layer, an elastic layer, a first insulation layer, a metal trace, a second insulation layer, and a bump. The passivation layer is formed on the substrate, and has one pad. The elastic layer is formed on the passivation layer. The first insulation layer is formed on the passivation layer and the elastic layer, and has a junction in contact with the pad. The metal trace is formed on the first insulation layer. The second insulation layer is formed on the metal trace, and a groove is formed correspondingly above the elastic layer. The bump is formed in the groove. An annular trench can be further formed around the bump. A groove can be furthermore formed in the first insulation layer correspondingly below the bump.

This non-provisional application claims priority under 35 U.S.C. §119(a) on Patent Application No(s). 096114667 filed in Taiwan, R.O.C. on Apr. 25, 2007, the entire contents of which are hereby incorporated by reference.

### BACKGROUND OF THE INVENTION

1. Field of Invention

The present invention relates to a wafer level package and a manufacturing method thereof, and more particularly to a wafer level package and a manufacturing method thereof, which can protect a metal trace, and solve the breaking problem generated when the metal trace directly contacts an elastic layer, without affecting the elasticity of the ultra-flexible elastic layer.

2. Related Art

A wafer level chip scale package is an important technique for assembling chips and circuit boards. The difference between this technique and the conventional flip chip package technique is that, since the difference between thermal expansion coefficients of the chips (using silicon as substrate) and the circuit board material is great, after the chips are assembled and when performing reliability testing, crack is likely to occur at the solder ball pads, thereby affecting the electrical connection. Therefore, a step of underfill is added in the flip chip package technique to protect the solder balls from being damaged. However, as the underfill step is time-consuming, and restoration is hard to be performed after the underfill is finished. Therefore, the wafer level chip scale package technique is developed to replace the conventional flip chip package technique.

As the wafer level chip scale package technique has more preferred electrical performance and lower fabrication cost compared with other package manners, and is a re-workable package technique, this technique will play a more and more important role in the production of future electronic products.

According to relevant prior arts, an elastic layer is used to protect the solder ball pads, to avoid the solder balls from cracking due to different thermal expansion coefficients of the silicon substrate and the printing circuit board, thus affecting the electrical conductivity of the package. Generally, a more flexible elastic layer provides more preferred stress relief effect, and therefore better satisfies the package requirements of future high I/O.

The technical idea of such an elastic layer can refer to U.S. patents such as U.S. Pat. No. 6,433,427, U.S. Pat. No. 6,914,333, U.S. Pat. No. 6,998,718. However, in these patents, the metal trace is directly in contact with the elastic layer. Therefore, when the future integrated circuit device has high I/O or the size of the solder balls must be reduced, in order to provide enough pad protection, a more flexible material of the elastic layer must be employed to provide necessary protection, and the circumstance that the metal trace is broken by being pulled may occur.

Although a more flexible elastic layer has preferred flexibility, in another aspect, it also means an extremely large thermal expansion coefficient and tensility. Therefore, when the flexible elastic layer is integrated with the metal trace with low thermal expansion coefficient and low tensility, the circumstance that the metal trace is broken tends to occur, thus causing breaking of the circuit.

### SUMMARY OF THE INVENTION

The present invention is directed to a wafer level package, in which an insulation layer is used to protect a metal trace, and an ultra-flexible material serves as an elastic layer for releasing the stress of solder ball pads, so as to avoid crack as well as the breaking problem of the metal trace.

In an embodiment of the present invention, the wafer level package includes a substrate, a passivation layer, an elastic layer, a first insulation layer, a metal trace, a second insulation layer, and a bump. The passivation layer is formed on the substrate, and has at least one pad. The elastic layer is formed on the passivation layer. The first insulation layer is formed on the passivation layer and the elastic layer, and is provided with a junction in contact with the pad. The metal trace is formed on the first insulation layer. The second insulation layer is formed on the metal trace, and a groove is formed correspondingly above the elastic layer. The bump is formed in the groove.

In another embodiment of the present invention, the wafer level package further includes an annular trench formed around the bump.

In still another embodiment of the present invention, the wafer level package includes a substrate, a passivation layer, an elastic layer, a first insulation layer, a metal trace, a second insulation layer, and a bump. The passivation layer is formed on the substrate, and has at least one pad. The elastic layer is formed on the passivation layer. The first insulation layer is formed on the passivation layer and the elastic layer, and is provided with a junction in contact with the pad. A first groove is formed in the first insulation layer correspondingly above the elastic layer. The metal trace is formed on the first insulation layer and in the first groove. The second insulation layer is formed on the metal trace, and has a second groove formed correspondingly above the elastic layer. The bump is formed in the second groove.

In an embodiment of the present invention, a polymer insulation layer is added between the metal trace and the elastic layer. The material feature of the insulation layer may not affect the reliability of the metal trace, thus providing protection for the metal trace, so as to prevent the metal trace from cracking due to the influence of the material of the elastic layer with extremely large thermal expansion coefficient.

In another aspect of the present invention, in order to prevent the material feature of the additionally added insulation layer from affecting the original effect of the elastic layer, an annular trench is formed around the bump, such that the elastic effect may not be affected.

In another aspect of the present invention, a groove is designed on the metal trace correspondingly below the bump, such that the first groove is smaller than the second groove, and the bump directly contacts the elastic layer. Therefore, not only the metal trace is protected, but the elastic effect of the bump is further enhanced.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

The appended drawings are used in order to more particularly describe embodiments of the present invention. Understanding that these drawings depict only typical embodiments of the invention and are not therefore to be considered to be limiting of its scope, the embodiments will be described and explained with additional specificity and detail through the use of the accompanying drawings in which:

FIG. 1 is a schematic structural view of a wafer level package according to a first embodiment of the present invention.

FIG. 2 is a schematic structural view of a wafer level package according to a second embodiment of the present invention.

FIG. 3 is another schematic structural view of the wafer level package according to the first embodiment of the present invention.

FIG. 4 is another schematic structural view of the wafer level package according to the second embodiment of the present invention.

FIG. 5 is a schematic structural view of a wafer level package according to a third embodiment of the present invention.

FIG. 6 is a schematic structural view of a wafer level package according to a fourth embodiment of the present invention.

FIG. 7 is another schematic structural view of the wafer level package according to the third embodiment of the present invention.

FIG. 8 is another schematic structural view of the wafer level package according to the fourth embodiment of the present invention.

### DETAILED DESCRIPTION OF THE INVENTION

The detailed features and advantages of the present invention will be described in detail in the following embodiments. Those skilled in the arts can easily understand and implement the content of the present invention. Furthermore, the relative objectives and advantages of the present invention are apparent to those skilled in the arts with reference to the content disclosed in the specification, claims, and drawings.

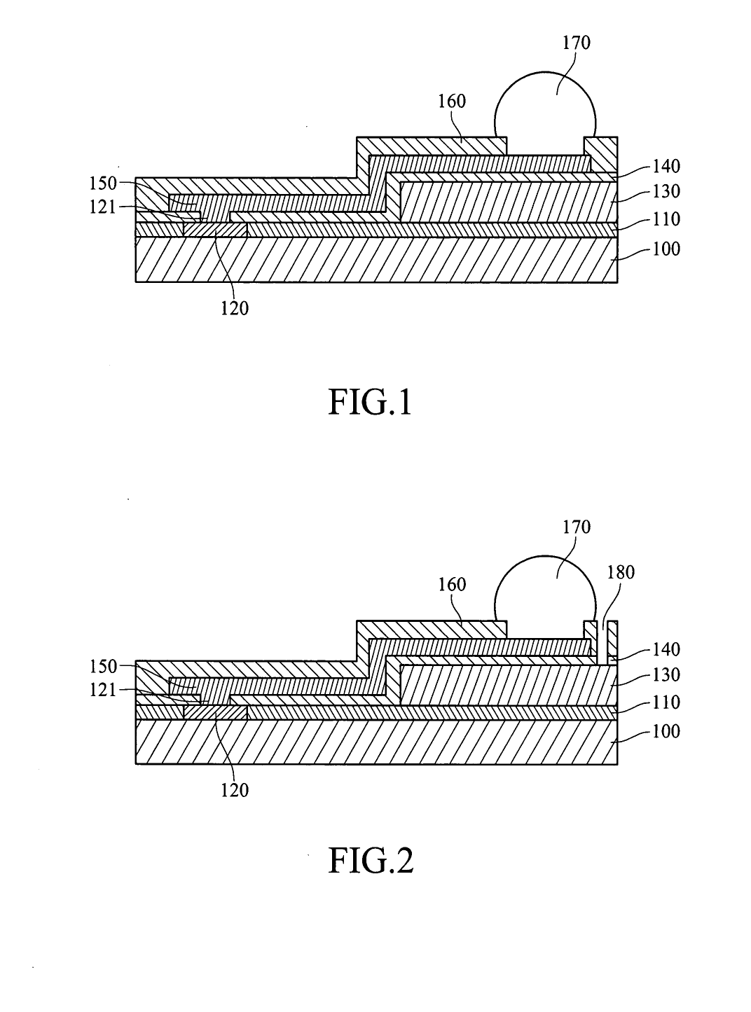

Referring to FIG. 1, a schematic structural view of a wafer level package according to a first embodiment of the present invention is shown.

As shown in the figure, the wafer level package includes a substrate 100, a passivation layer 110, an elastic layer 130, a first insulation layer 140, a metal trace 150, a second insulation layer 160, and a bump 170.

The passivation layer 110 is formed on the substrate 100, and has at least one pad 120. The elastic layer 130 is formed on the passivation layer 110. The first insulation layer 140 is formed on the passivation layer 110 and the elastic layer 130, and has a junction 121 in contact with the pad 120. The metal trace 150 is formed on the first insulation layer 140, and is in contact with the junction 121, so as to form an electrical connection. The second insulation layer 160 is formed on the metal trace 150, and has a groove formed correspondingly above the elastic layer 130. The bump 170 is formed in the groove.

The substrate 100 is usually a silicon chip. After a required circuit is fabricated on the substrate 100 through a semiconductor process, external signals are guided in through the pads 120 on the surface of the substrate 100, so as to control the action of the substrate 100.

In the present invention, the metal trace 150 is pulled from its original position of the pad 120 to be above the elastic layer 130 by means of redistribution layer (RDL), and the bump 170 is formed at a position above the metal trace 150, so as to conduct the pad 120 and the bump 170, such that the substrate 100 and a circuit board disposed above (not shown) are electrically conducted.

Referring to FIG. 2, a schematic sectional view of a wafer level package according to a second embodiment of the present invention is shown, which has an architecture similar to that of FIG. 1, but is further provided with an annular trench 180 formed around the bump 170.

According to the structure of FIG. 2, in order to prevent the material feature of the additionally added insulation layer from affecting the original effect of the elastic layer, an annular trench is formed around the bump 170, such that the elastic effect may not be affected.

In the structures shown in FIG. 1 and FIG. 2, a polymer insulation layer, i.e., the previous first insulation layer 140, is added between the metal trace 150 and the elastic layer 130. The material feature of the insulation layer may not affect the reliability of the metal trace 150, thus providing protection for the metal trace 150, so as to prevent the metal trace 150 from cracking due to the influence of the material of the elastic layer with extremely large thermal expansion coefficient.

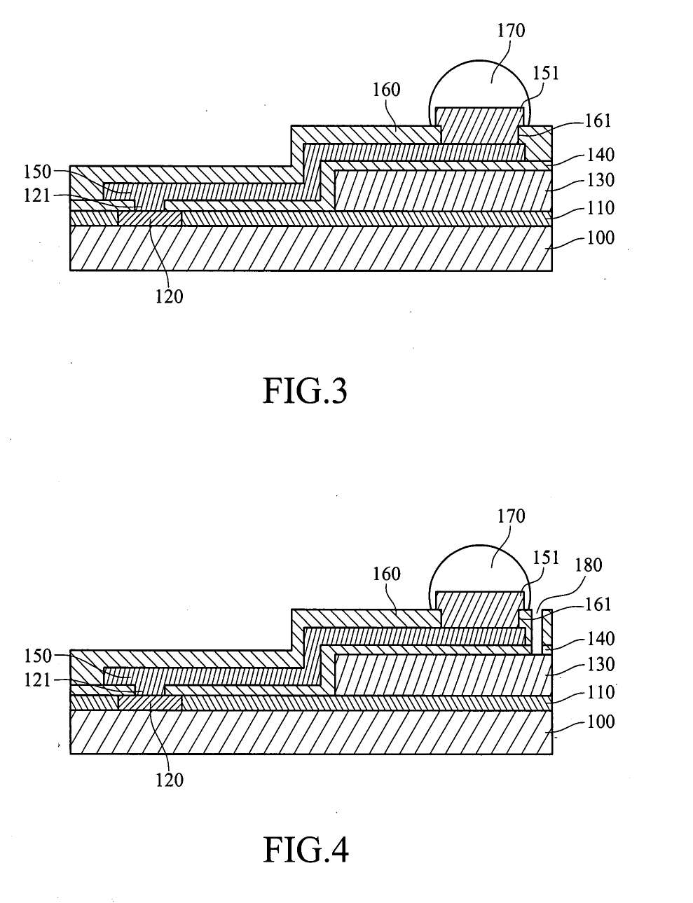

In other embodiments, in the structures shown in FIG. 1 and FIG. 2, a second metal layer 151 is further formed in the groove 161 of the second insulation layer 160, as shown in FIG. 3 and FIG. 4, and the second metal layer 151 is formed between the bump 170 and the metal trace 150. The second metal layer 151 mainly serves as a barrier for dispersion, and as a wetting layer when forming the bump 170.

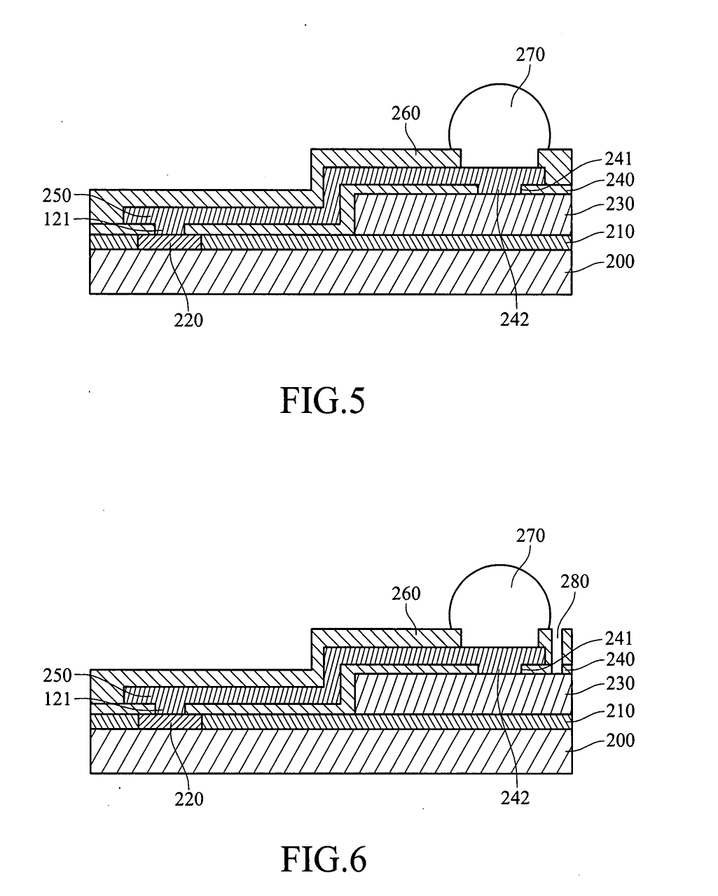

Referring to FIG. 5, a schematic structural view of a wafer level package according to a third embodiment of the present invention is shown.

As shown in the figure, the wafer level package includes a substrate 200, a passivation layer 210, an elastic layer 230, a first insulation layer 240, a metal trace 250, a second insulation layer 260, and a bump 270.

The passivation layer 210 is formed on the substrate 200, and has at least one pad 220. The elastic layer 230 is formed on the passivation layer 210. The first insulation layer 240 is formed on the passivation layer 210 and the elastic layer 230, and has a first junction 221 in contact with the pad 220. In the first insulation layer 240, a first groove is formed at a position corresponding to the elastic layer 230. The metal trace 250 is formed on the first insulation layer 240, and is in contact with the first junction 221. When forming the metal trace 250, a portion of the metal material is filled in the first groove 241, to form a second junction 242. The second insulation layer 260 is formed on the metal trace 250, and has a second groove formed correspondingly above the elastic layer 230. The bump 270 is formed in the second groove.

Referring to FIG. 6, a schematic structural view of a wafer level package according to a fourth embodiment of the present invention is shown, which has an architecture similar to that of FIG. 5, but is further provided with an annular trench 280 formed around the bump 270.

According to the structure shown in FIG. 6, in order to prevent the material feature of the additionally added insulation layer from affecting the original effect of the elastic layer, an annular trench 280 is formed around the bump 270, such that the elastic effect may not be affected.

According to the structures shown in FIG. 5 and FIG. 6, a first groove smaller than the second groove is designed below the bump. As such, the bump is capable of being directly in contact with the elastic layer, and protecting the metal trace at the same time, thereby further enhancing the elastic effect of the bump, so as to solve the problems of the reliability of the bump.

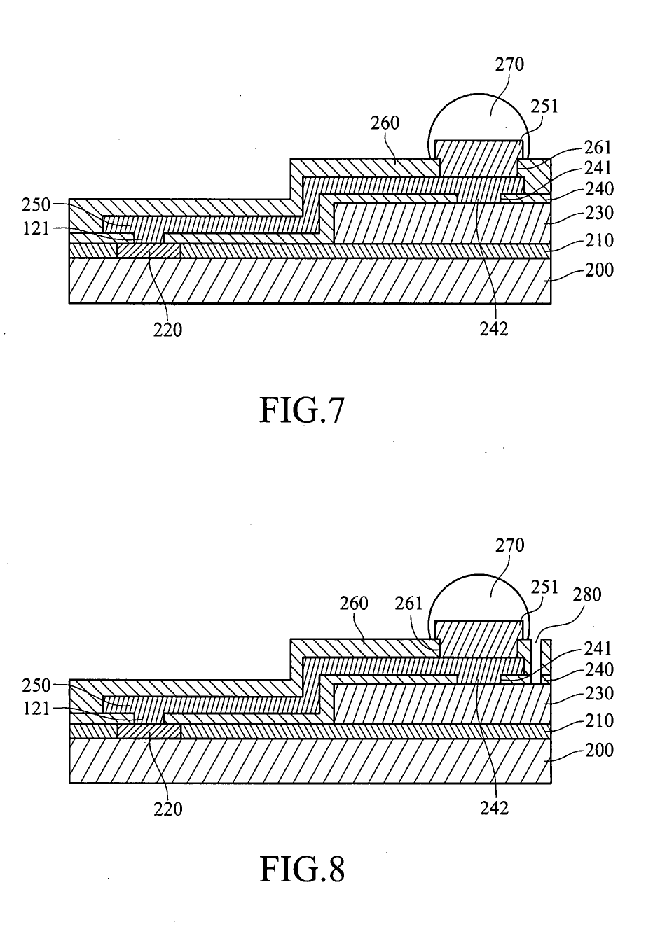

In other embodiments, in the structures shown in FIG. 5 and FIG. 6, a second metal layer 251 is further formed in the groove 261 of the second insulation layer 260, as shown in FIG. 7 and FIG. 8, and the second metal layer 251 is formed between the bump 270 and the metal trace 250. The second metal layer 251 mainly serves as a barrier for dispersion, and as a wetting layer when forming the bump 270.

In the above embodiments, Young's Modulus of the elastic layer is smaller than 500 MPa.

In the above embodiments, the material of the first insulation layer is epoxy, polyimide (PI), bnzocyclobutene (BCB), copolymers based thereon or combinations thereof. The material of the second insulation layer is epoxy, polyimide (PI), bnzocyclobutene (BCB), copolymers based thereon or combinations thereof. The material of the metal trace is TiW/Cu, TiW/Cu/Ni/Au, Ti/Cu, Ti/Cu/Ni/Au, or Ti/Al.

The manufacturing flow of the present invention includes: first, forming a polymer elastic layer on the surface of the wafer by means of coating, printing, or compression; next, forming a first insulation layer by means of photolithography; then, forming a metal trace by means of sputtering or plating; afterward, forming a second insulation layer; and finally, forming a conductive bump by means of printing or plating or planting.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A wafer level package, comprising:
a substrate;
a passivation layer, formed on the substrate, and having at least one pad;
an elastic layer, formed on the passivation layer;
a first insulation layer, formed on the passivation layer and the elastic layer, and having a junction in contact with the pad;
a metal trace, formed on the first insulation layer;
a second insulation layer, formed on the metal trace, and having a groove formed correspondingly above the elastic layer; and
a bump, formed in the groove.

2. The wafer level package as claimed in claim 1, further comprising an annular trench formed around the bump.

3. The wafer level package as claimed in claim 1, wherein Young's Modulus of the elastic layer is smaller than 500 MPa.

4. The wafer level package as claimed in claim 1, wherein the material of the first insulation layer comprises epoxy, polyimide (PI), bnzocyclobutene (BCB), copolymers based thereon or combinations thereof.

5. The wafer level package as claimed in claim 1, wherein the material of the second insulation layer comprises epoxy, polyimide (PI), bnzocyclobutene (BCB), copolymers based thereon or combinations thereof.

6. The wafer level package as claimed in claim 1, wherein the material of the metal trace comprises TiW/Cu, TiW/Cu/Ni/Au, Ti/Cu, Ti/Cu/Ni/Au, or Ti/Al.

7. The wafer level package as claimed in claim 1, wherein a second metal layer is further formed in the groove of the second insulation layer, and the second metal layer is formed between the bump and the metal trace.

8. A wafer level package, comprising:
a substrate;
a passivation layer, formed on the substrate, and having at least one pad;
an elastic layer, formed on the passivation layer;
a first insulation layer, formed on the passivation layer and the elastic layer, having a junction in contact with the pad, and having a first groove formed correspondingly above the elastic layer;
a metal trace, formed on the first insulation layer and in the first groove;
a second insulation layer, formed on the metal trace, and having a second groove formed correspondingly above the elastic layer; and
a bump, formed in the second groove.

9. The wafer level package as claimed in claim 8, further comprising an annular trench formed around the bump.

10. The wafer level package as claimed in claim 8, wherein the first groove is smaller than the second groove.

11. The wafer level package as claimed in claim 8, wherein Young's Modulus of the elastic layer is smaller than 500 MPa.

12. The wafer level package as claimed in claim 8, wherein the material of the first insulation layer comprises epoxy, polyimide (PI), bnzocyclobutene (BCB), copolymers based thereon or combinations thereof.

13. The wafer level package as claimed in claim 8, wherein the material of the second insulation layer comprises epoxy, polyimide (PI), bnzocyclobutene (BCB), copolymers based thereon or combinations thereof.

14. The wafer level package as claimed in claim 8, wherein the material of the metal trace comprises TiW/Cu, TiW/Cu/Ni/Au, Ti/Cu, Ti/Cu/Ni/Au, or Ti/Al.

15. The wafer level package as claimed in claim 8, wherein a second metal layer is further formed in the second groove of the second insulation layer, and the second metal layer is formed between the second bump and the metal trace.
